(19) United States
(12) Patent Application Publication
(10) Pub. No.: US 2026/0013246 A1
(43) Pub. Date: Jan. 8, 2026

(54) IMAGE SENSOR WITH THIN FILM TRANSISTORS

(71) Applicant: OMNIVISION TECHNOLOGIES, INC., Santa Clara, CA (US)

(72) Inventors: Nagataka TANAKA, Kanagawa (JP); Sohei MANABE, San Jose, CA (US); Osamu FUJII, Kanagawa (JP); Weili CAI, Kanagawa (JP)

(73) Assignee: OMNIVISION TECHNOLOGIES, INC., Santa Clara, CA (US)

(21) Appl. No.: 19/247,010

(22) Filed: Jun. 24, 2025

Related U.S. Application Data
(60) Provisional application No. 63/668,367, filed on Jul. 8, 2024.

(51) Int. Cl. H10F 39/00

(52) U.S. Cl. CPC H10F 39/80373; H10F 39/80377; H10F 39/8057; H10F 39/811

(57) ABSTRACT

The image sensor comprises a semiconductor layer, a transfer gate, an inter-layer dielectric layer, and an upper dielectric layer. The semiconductor layer has a first side and a second side opposite to the first side. The semiconductor layer includes a photodiode doped region. The transfer gate on the semiconductor layer is coupled the photodiode region to a floating diffusion. The inter-layer dielectric layer is disposed on the semiconductor layer. The upper dielectric layer is disposed on the inter-layer dielectric layer. The upper dielectric layer includes a second semiconductor layer on the inter-layer dielectric layer. The second semiconductor layer has a transistor coupled to the floating diffusion through a semiconductor connection structure. The semiconductor connection structure extend through the inter-layer dielectric layer to connect a source electrode of the transistor to the floating diffusion.

### CROSS REFERENCE TO RELATED APPLICATION

This application claims priority to the provisional application No. 63/668,367, filed on Jul. 8, 2024, which is incorporated herein by reference in its entirety including the specification, claims, drawings, and abstract.

### TECHNICAL FIELD

This disclosure relates to an image sensor and more particularly but not exclusively relates to an image sensor with pixel using thin film transistors.

### BACKGROUND

Image sensors have become ubiquitous and are now widely used in digital cameras, cellular phones, security cameras, as well as, medical, automobile, and other applications. As image sensors are integrated into a broader range of electronic devices it is desirable to enhance their functionality, performance metrics, and the like in as many ways as possible (e.g., resolution, power consumption, dynamic range, etc.) through both device architecture design as well as image acquisition processing.

The typical image sensor operates in response to image light reflected from an external scene being incident upon the image sensor. The image sensor includes an array of pixels having photosensitive elements (e.g., photodiodes) that absorb a portion of the incident image light and generate image charge upon absorption of the image light. The image charge of each of the pixels may be measured as an output voltage of each photosensitive element that varies as a function of the incident image light. In other words, the amount of image charge generated is proportional to the intensity of the image light, which is utilized to produce a digital image (i.e., image data) representing the external scene.

Ongoing reduction in pixel size for widening image sensor applications such as mobile, augment reality/virtual reality, a design challenge arise in devising pixel layout and pixel structure that maximize pixel area to achieve high full well capacity and quantum efficiency.

There has been a continuous need for a cost-effective pixel architecture that can effectively utilize limited space to maximize light sensitivity of pixels to improve image resolution and image quality of image sensor.

### SUMMARY

In this specification, the image sensor is disclosed. The image sensor comprises a semiconductor layer, a transfer gate, an inter-layer dielectric layer, and an upper dielectric layer. The semiconductor layer has a first side and a second side opposite to the first side. And the semiconductor layer includes a photodiode region. The transfer gate on the semiconductor layer is coupled the photodiode region to a floating diffusion. The inter-layer dielectric layer is disposed on the semiconductor layer. The upper dielectric layer is disposed on the inter-layer dielectric layer. The upper dielectric layer includes a second semiconductor layer disposed on the inter-layer dielectric layer. The second semiconductor layer has a transistor formed thereon. The transistor is coupled to the floating diffusion through a semiconductor connection structure. The semiconductor connection structure is arranged to extend through the inter-layer dielectric layer to connect a source electrode of the transistor to the floating diffusion.

In one embodiment, the transistor may be a thin film transistor or TFT transistor.

In one embodiment, the transistor may be a cylindrical type of thin film transistor.

In one embodiments, the upper dielectric material layer may include a first contact connecting to the source electrode of the transistor, a second contact connecting to a gate of the transistor, and a third contact connecting to a drain electrode of the transistor.

In one embodiments, the upper dielectric layer further may include a second transistor having a second gate on the second semiconductor layer and a third transistor having a third gate on the second semiconductor layer.

In one embodiments, the transistor may be a reset transistor.

In one embodiment, the second gate of the second transistor may be coupled to the source electrode of the transistor through at least one metal interconnect.

In the same or different embodiments, the at least one metal interconnect may be included in a metal layer disposed on the upper dielectric layer.

In one embodiment, the second transistor may be a source follower transistor and the third transistor may be a row select transistor coupled to a bit line.

In one embodiment, the second transistor and the third transistor may be TFT transistors.

In one embodiment, the second transistor and the third transistor are cylindrical type of TFT transistors.

In one embodiment, the semiconductor connection structure may comprise an amorphous silicon or polysilicon material.

In one embodiment, the semiconductor connection structure and the second semiconductor material layer may have substantially same material composition.

In one embodiment, the image sensor may further comprises a light shield disposed in the inter-layer dielectric, the light shield being further disposed between the second semiconductor layer and the semiconductor layer.

In one embodiment, the pixel structure is disclosed. The pixel array comprises the semiconductor layer, the transfer gate, the upper dielectric layer, and the second semiconductor layer.

In one embodiment, the pixel array is disclosed. The pixel structure comprises the semiconductor layer, the transfer gate, the upper dielectric layer, and the second semiconductor layer.

In one embodiment, the imaging system is disclosed. The imaging system comprises the semiconductor layer, the transfer gate, the upper dielectric layer, and the second semiconductor layer.

### BRIEF DESCRIPTION OF DRAWINGS

Non-limiting and non-exhaustive examples of the invention are described with reference to the following figures, and like reference numerals refer to like parts throughout the various views unless otherwise specified, wherein:

wherein:

FIG. 1A shows an example of a schematic diagram of a pixel circuit according to an exemplary embodiment of present disclosure.

FIG. 1B shows an example of a stacking structure of an image sensor according to an exemplary embodiment of present disclosure.

FIG. 2A shows a schematic diagram of a stacked structure for a unit pixel included in an image sensor provided in accordance to a first embodiment of present disclosure.

FIG. 2B shows an enlarged structural view of FIG. 2A in accordance to the first embodiment of present disclosure.

FIG. 2C shows an example of stacked pixel architecture with TFT transistor in accordance to a second embodiment of present disclosure.

FIG. 3 shows an example pixel layout for the stacked pixel architecture with TFT transistor in accordance to teaching of the present disclosure.

FIG. 4 shows an example of stacked pixel architecture with a light shield in accordance to a third embodiment of present disclosure.

FIG. 5 shows an alternative configuration of stacked pixel architecture with a light shield in accordance to an embodiment of present disclosure.

FIG. 6 shows an example pixel layout for the stacked pixel architecture in accordance to an embodiment of present disclosure.

FIGS. 7A and 7B show examples of stacked pixel structure included a cylindrical type TFT transistor structure in accordance to an embodiment of present disclosure.

FIG. 8 illustrates a block diagram of an imaging system accordance to the present disclosure.

### DESCRIPTION OF EMBODIMENTS

The term “first”, “second” or the like used herein may modify various elements regardless of order and/or priority, but does not limit the elements. Such terms may be used to distinguish one element from another element. For example, “a first user device” and “a second user device” may indicate different user devices regardless of order, or formation sequence, or priority. For example, without departing the scope of the present disclosure, a first element may be referred to as a second element and vice versa.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

Further, it will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

Further still, it will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element or layer, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

The term “have”, “may have”, “include”, “may include” or “comprise” used herein indicates the existence of a corresponding feature (e.g., a number, a function, an operation, or an element) and does not exclude the existence of an additional feature.

The term “A or B”, “at least one of A and/or B”, or “one or more of A and/or B” may include all possible combinations of items listed together. For example, the term “A or B”, “at least one of A and B”, or “at least one of A or B” may indicate all the cases of (1) including at least one A, (2) including at least one B, and (3) including at least one A and at least one B.

It will be understood that when a certain element (e.g., a first element) is referred to as being “operatively or communicatively coupled with/to” or “connected to” another element (e.g., a second element), the certain element may be coupled to the other element directly or via another element (e.g., a third element). However, when a certain element (e.g., a first element) is referred to as being “directly coupled” or “directly connected” to another element (e.g., a second element), there may be no intervening element (e.g., a third element) between the element and the other element.

The term “configured (or set) to” may be interchangeably used with the term, for example, “suitable for”, “having the capacity to”, “designed to”, “adapted to”, “made to”, or “capable of”. The term “configured (or set) to” may not necessarily have the meaning of “specifically designed to”. In some cases, the term “device configured to” may indicate that the device “may perform” together with other devices or components. For example, the term “processor configured (or set) to perform A, B, and C” may represent a dedicated processor (e.g., an embedded processor) for performing a corresponding operation, or a generic-purpose processor (e.g., a CPU or an application processor) for executing at least one item of software or program stored in a memory device to perform a corresponding operation.

The term “p-type” defines a structure, layer, and/or region in a substrate material layer (e.g., semiconductor substrate or epitaxial layer) as being doped with p-type dopant, such as boron.

The term “n-type” defines a structure, layer, and/or region in a substrate material layer (e.g., semiconductor substrate or epitaxial layer) as being doped with n-type dopant, such as phosphorus and/or arsenic. It is appreciated that the term “photodiode doped region” may correspond to a region within the semiconductor substrate that has been doped, for example by ion implantation, to have an opposite charge carrier type (i.e., conductivity type) relative to the majority charge carrier type of the semiconductor substrate such that an outer perimeter of the doped region (e.g., herein referred to as a photodiode region) forms a PN junction or a PIN junction of a photodiode. For example, an N-doped region, formed in a P-type semiconductor substrate, forms a corresponding photodiode region. In some embodiments, a given pixel may further include a pinning region (e.g., a doped region disposed between a side of the semiconductor substrate and the photodiode doped region having a conductivity type opposite of the photodiode doped region conductivity type) to form a pinned photodiode. For example, the pinning region has a P-type conductivity and the photodiode doped region has an N-type conductivity.

In some embodiments, the term “about” and the term “substantially” can refer to a value of a given quantity or manufacturing parameters that varies within 5% of the value (e.g., ±1%, ±2%, +3%, ±4%, ±5% of the value). These values are merely examples and are not intended to be limiting. The terms “about” and “substantially” can refer to a percentage of the values as interpreted by those skilled in relevant art(s) in light of the teachings of the present disclosure.

In the following description, numerous specific details are given to provide a thorough understanding of embodiments. The embodiments can be practiced without one or more of the specific details, or with other methods, components, materials, etc. In other instances, well-known structures, materials, or operations, such as, for example, processors, spectrometers, etc., are not shown or described in detail to avoid obscuring aspects of the embodiments.

The present disclosure provides a pixel structure that uses thin film transistor (TFT) architecture to form two-layer pixel structure without using additional wafer substrate, which can effective maximize pixel area for small pixels while lower fabrication cost. In various of examples, a pixel structure incorporates thin film transistor (TFT) architecture to form pixel transistors e.g., source follower transistors, reset transistors, row select transistors enabling pixel area of the pixel to be fully utilized maximizing associated photodiode area, thereby maximize full well capacity and quantum efficiency.

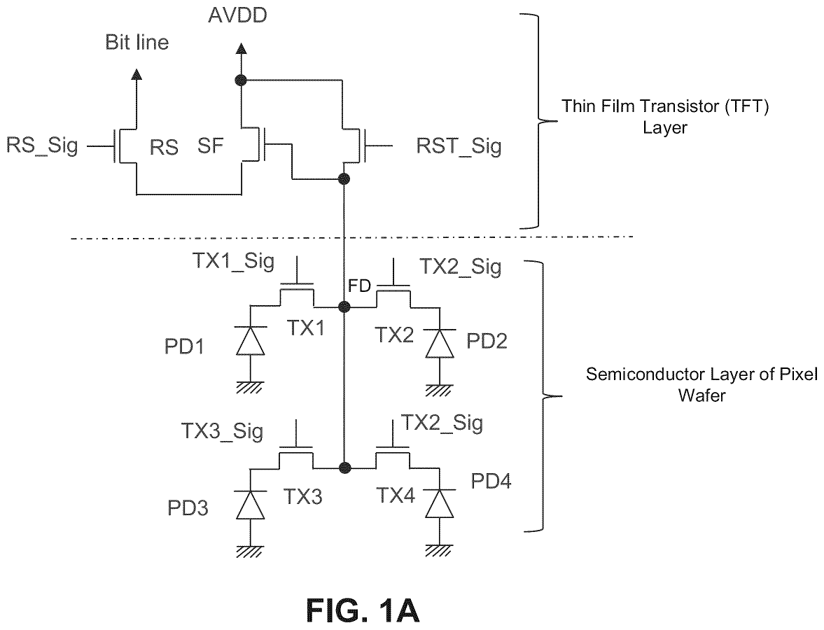

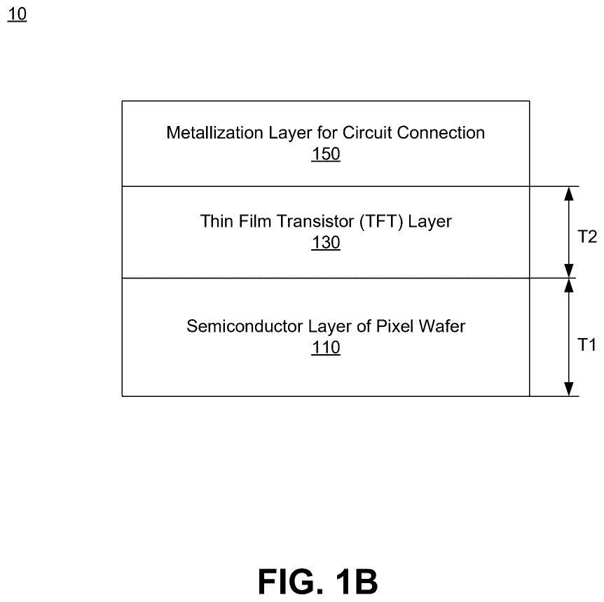

FIG. 1A shows a schematic of a pixel circuit in accordance to teaching of present disclosure.

A pixel 100 includes a plurality of photodiodes such as photodiodes PD1˜PD4, a plurality of transfer gates such as transfer gates TX1˜TX4, a floating diffusion FD, a source follower transistor SF, a reset transistor RST, and a row select transistor RS. The pixel 100 may be one of a plurality of pixels included in a pixel array of an image sensor. In the illustrated embodiments, the pixel 100 includes four photodidoes, but it is appreciated that the number of photodiodes included in the pixel 100 may be more or less. For example, the pixel 100 in other non-limiting embodiments, may include one, two, eight, and the like. The plurality of photodiodes PD1˜PD4 is coupled to the floating diffusion FD through the plurality of transfer gates TX1˜TX4. The floating diffusion FD herein is a shared or common floating diffusion to the plurality of photodiodes PD1˜PD4. Photodiode PD1 is selectively coupled to the floating diffusion FD through transfer gate TX1. Photodiode PD2 is selectively coupled to the floating diffusion FD through transfer gate TX2. Photodiode PD3 is selectively coupled to the floating diffusion FD through transfer gate TX3. Photodiode PD4 is selectively coupled to the floating diffusion FD through transfer gate TX4. Each of the plurality of transfer gates TX1˜TX4 is configured to selectively couple the corresponding photodiode to the floating diffusion FD transferring photo-generated charges from the corresponding photodiode to the floating diffusion in response to respective transfer signals TX1_Sig˜TX4_Sig. Transfer gate TX1 is configured to selectively couple the photodiode PD1 to the floating diffusion FD in response to transfer signal TX1_Sig (e.g., voltage signal with positive level). Transfer gate TX2 is configured to selectively couple the photodiode PD2 to the floating diffusion FD in response to transfer signal TX2_Sig (e.g., voltage signal with positive level). Transfer gate TX3 is configured to selectively couple the photodiode PD3 to the floating diffusion FD in response to transfer signal TX3_Sig (e.g., voltage signal with positive level). Transfer gate TX4 is configured to selectively couple the photodiode PD4 to the floating diffusion FD in response to transfer signal TX4_Sig (e.g., voltage signal with positive level).

The present disclosure provides a pixel structure that uses thin film transistor (TFT) architecture to form two-layer pixel structure without using additional wafer substrate, which can effective maximize pixel area for small pixels while lower fabrication cost. In various of examples, a pixel structure incorporates a stacking structure and utilizes thin film transistor (TFT) architecture to form pixel transistors e.g., source follower transistors, reset transistors, row select transistors enabling pixel area of the pixel to be fully utilized maximizing associated photodiode area, thereby maximize full well capacity and quantum efficiency.

The reset transistor RST is coupled between a power line and the floating diffusion FD to reset (e.g., discharge or charge floating diffusion FD to a preset voltage e.g., a supply voltage AVDD) under control of a reset signal RST_Sig. The reset transistor RST is further coupled to the plurality of photodiodes PD1˜PD4 through the respective transfer gates TX1˜TX4 to selective reset photodiode to the preset voltage. Floating diffusion FD is coupled to a gate of the source follower transistor SF. The source follower transistor is coupled between the power line and the row select transistor RS. The source follower transistor SF operates to modulate the image signal output based on the voltage of floating diffusion FD received at its gate, where the image signal corresponds to the amount photoelectrons accumulated each of the plurality of photodiodes PD1˜PD4 during an integration period. The row select transistor RS selectively couples the output (e.g., image signal) of the source follower transistor RS to the readout column line under control of a row select signal RS_Sig.

An exemplary operation of the pixel 100 may include a precharge period, an integration period subsequent to the precharge period, and a readout period subsequent to the integration period. In operation, during the precharge period, the floating diffusion FD and each of photodiodes PD1˜PD4 are reset to a predetermined voltage level, depleting charges in a photodiode doped region of each of photodiodes PD1˜PD4. During the integration period (also referred to as an exposure or accumulation period) of the pixel, the photodiode doped region of each of photodiodes PD1˜PD4 detects or absorbs light incident on the photosensitive area of the pixel. The photogenerated charge(s) accumulated in the photodiode region of each photodiodes PD1˜PD4 is indicative of the amount of light incident on the photodiode region of each individual photodiode PD1˜PD4. After the integration period, the plurality of transfer gates TX1˜TX4 is turned on to transfer the photogenerated charge(s) to floating diffusion FD upon reception of a corresponding transfer signal TX1_Sig˜TX4_Sig(e.g., a positive biasing voltage) during the readout period. The source follower transistor SF generates the image signal. The row select transistor RS coupled to the source follower transistor then selectively reads out the signal onto a column bit line for subsequent image processing.

In the illustrated embodiment, the plurality of photodiodes PD1˜PD4, the plurality of transfer gates TX1˜TX4, and the floating diffusion FD are formed in or on a semiconductor material layer (may also referred to as semiconductor layer). The reset transistor RST, the source follower transistor, and a row select transistor RS may be formed on a thin film transistor (TFT) layer that is stacked on the semiconductor layer as illustrated in FIG. 1B. FIG. 1B shows an example stacking structure of an image sensor having the pixel described in FIG. 1A provided in accordance to the teaching of present disclosure.

The image sensor architecture 10 may include a pixel wafer having a semiconductor layer 110 with a pixel array formed thereon, a thin film transistor (TFT) layer 130, and a metallization layer 150. The TFT layer 130 may be stacked on semiconductor layer 110, and the metallization layer 150 may be stacked on the TFT layer 130. That is, the TFT layer 130 may be sandwiched between the metallization layer 150 and the semiconductor layer 110. In embodiments, a first depthwise thickness T1 of the semiconductor layer 110 may be greater than a second depthwise thickness T2 of TFT layer 130. The semiconductor layer 110 of the pixel wafer may have photodiodes, transfer gates, and floating diffusion formed thereon. The TFT layer 130 having TFT transistors disposed thereon configured to form as source follower transistor, reset transistor and row select transistor. A connection between floating diffusion and the source follower transistor SF/reset transistor RST may be formed via a polysilicon or amorphous silicon connection structure. The metallization layer 150 may include one or more metal layer having metal interconnects for forming circuit connections between transistors in TFT layer 130 and the pixel components (e.g., transfer gates, ground contact) on the semiconductor layer 110.

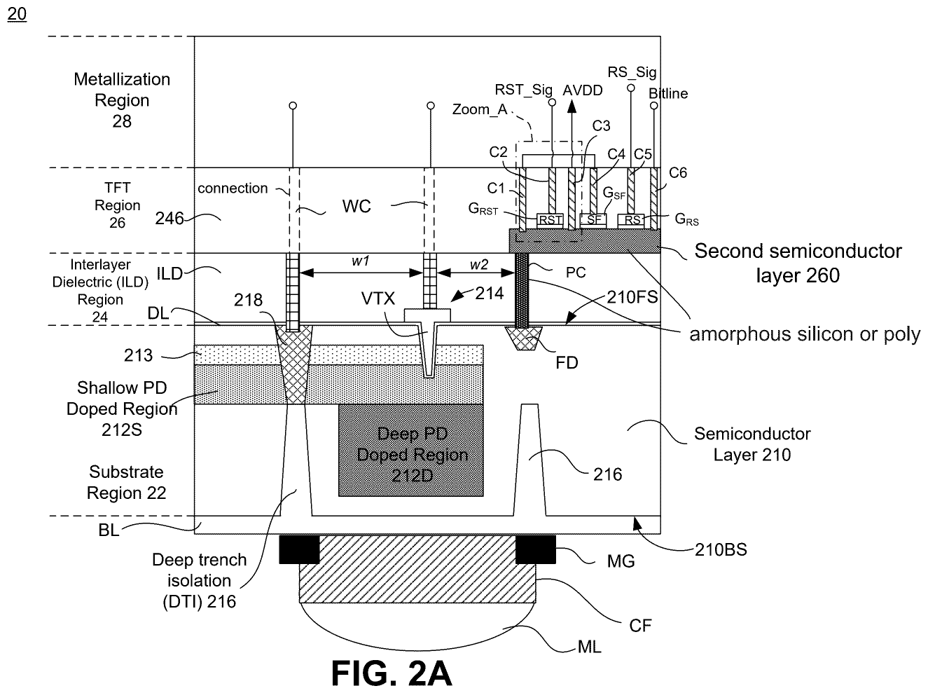

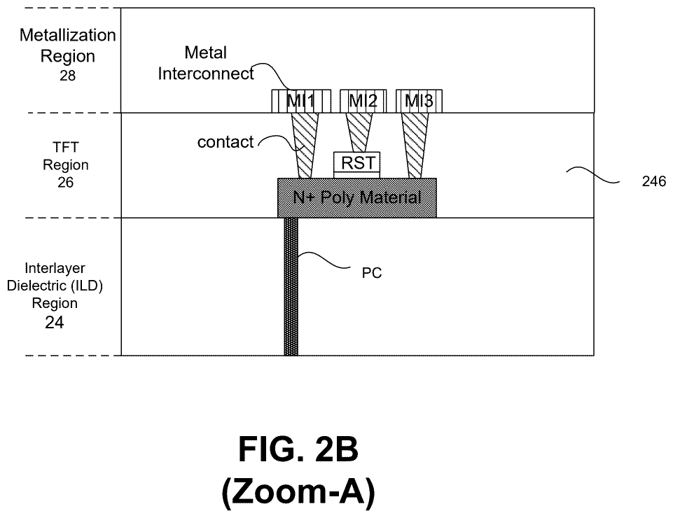

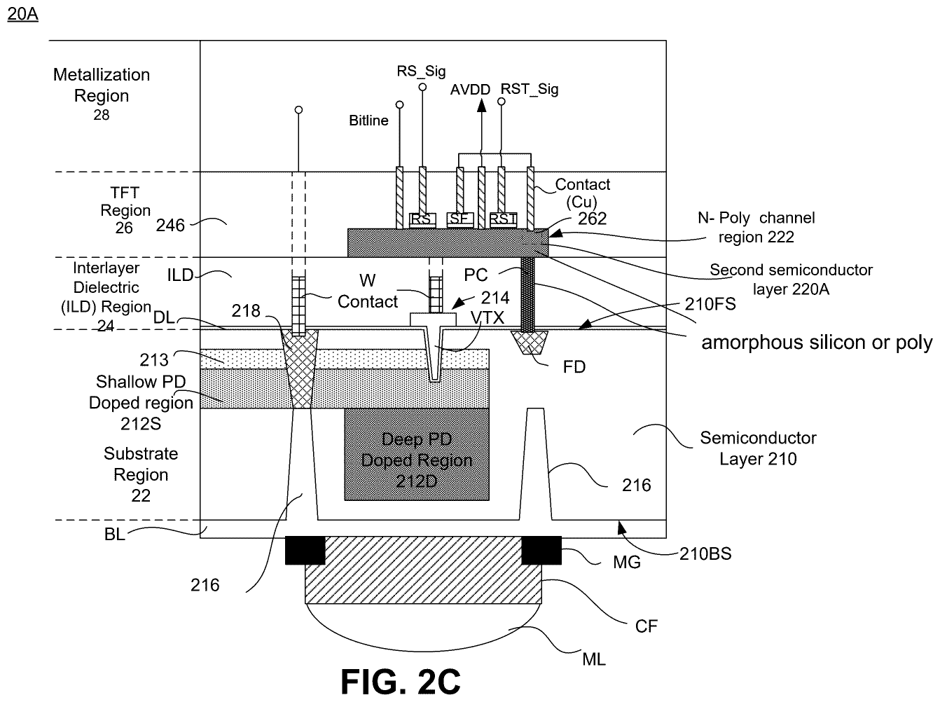

FIG. 2A shows a device schematic of a stacked structure 20 for a unit pixel included in an image sensor provided in accordance to an embodiment of the present disclosure. The unit pixel may be included in a plurality of pixels arranged in an array form. FIG. 2B shows a zoom-in structural view of FIG. 2A. The single stacked pixel structure as aforementioned includes a semiconductor region 22, an interlayer dielectric region 24, a thin film transistor (TFT) region 26, and a metallization region 28. In the illustrated embodiment, source follower transistor SF, reset transistor RST, and row select transistor RS are TFT transistors formed in TFT region.

The substrate region 22 includes a semiconductor layer 210 (the first semiconductor layer) having at least a photodiode having a photodiode doped region, a floating diffusion FD, deep trench isolation structure 216 and a transfer gate 214 formed thereon, a color filter CF, metal grid MG, and a microlens ML.

It is appreciated that the semiconductor layer 210 (the first semiconductor layer) may correspond to a part of or an entirety of a semiconductor wafer (e.g., a silicon wafer) that is configured as pixel wafer. In some embodiments, the semiconductor substrate includes or is otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof. More specifically, the semiconductor layer 210 may correspond to any semiconductor material or combination of materials that may be doped or otherwise configured to facilitate the plurality of photodiodes e.g., PD1, PD2, PD3, PD4 forming a photosensitive region of the respective pixel. For example, in some embodiments, the semiconductor layer 210 may correspond to one or more epitaxial layers (e.g., P or N doped silicon) formed on a carrier wafer. In such an embodiment, each of the photodiodes e.g., PD1, PD2, PD3, PD4, floating diffusion FD, P contact region may be formed in the one or more epitaxial layers corresponding to the semiconductor layer 210 while the carrier or support wafer may be removed or otherwise thinned during fabrication. For example, photodiodes e.g., photodiodes PD1, PD2, PD3, PD4, floating diffusion FD, P contact region may be formed by one or more ion implantation through a front side FS surface with various implantation energy. In one embodiment, the semiconductor layer 210 is formed of intrinsic or extrinsic silicon having regions doped sufficiently with appropriate type of impurities to form a photodiode doped region for a photodiode (e.g., photodiode PD1, PD2, PD3, PD4) that is capable of generating image charge in response to incident light. P contact region may be a region in the semiconductor layer 210 doped with dopant having conductive type same as that of the semiconductor layer 210 and opposite to the conductive type of photodiode doped region of individual photodiode.

The photodiode (e.g., photodiode PD1, PD2, PD3, PD4) includes a shallow PD doped region 212S and a deep PD doped region 212D. The shallow PD doped region 212S is disposed proximate to a front surface 210FS of the semiconductor layer 210, and the deep PD doped region 212D abuts and extends from the shallow PD doped region 212S toward a backside surface 210BS of the semiconductor layer 210. The shallow PD doped region and the deep PD doped region 212D collectively form a photodiode doped region for photo-generated and accumulated charges in response to an incident light directed by the microlens ML. The deep PD doped region 212D may be formed at a deeper implantation depth with respect to front surface 210FS of the semiconductor layer 210 than the shallow doped PD region 212S. The deep PD doped region 212D may have a junction depth greater than a junction depth of the shallow PD doped region 212S with respect to front surface 210FS of the semiconductor layer 210. The semiconductor layer 210 further includes an optional overflow doped region 213 disposed between the front surface 210FS and the shallow PD doped region 212S for facilitating charge transfer from the photodiode doped region to the floating diffusion FD. The transfer gate 214 disposed on front surface 210FS of the semiconductor layer 210 includes a vertical transfer gate VTX is disposed between the photodiode doped region and the floating diffusion FD. The vertical transfer gate VTX extends from the front surface 210FS of the semiconductor layer into the semiconductor layer 210. The vertical transfer gate VTX may extend through the overflow doped region 213 and into part of the shallow PD doped region 212S. The deep trench isolation structure 216 is disposed in the semiconductor layer 210 to separate adjacent pixels and provide isolation between photodiode doped regions of adjacent pixels. The deep trench isolation structure 216 is disposed to extend from backside surface 210BS of the semiconductor layer 210 into the semiconductor layer 210. A buffer or planarized layer BL may be disposed on the backside of the semiconductor layer for protecting underlying layer such as anti-reflective coating layer, surface passivation film form of high k material during formation of metal grid MG, color filters CF, and microlens ML. Metal grid MG may be disposed on the buffer or planarized layer BL for provide optical isolation between pixels above the semiconductor layer 210. Metal grid MG may be disposed in alignment with deep trench isolation structure 216 and defining an aperture that is optically aligned with photodiode region of the pixel. Color filter CF may be disposed in the aperture defined by the metal grid MG and optically aligned with photodiode region of the pixel. Microlens ML may disposed on the color filter CF for directing incident light to the photodiode doped region of the pixel.

In various of examples, the pixel may further include a P-type poly doped isolation structure 218 that extends from the front surface 210FS of the semiconductor layer 210 toward the backside surface 210BS of the semiconductor layer 210 (the first semiconductor layer). In embodiments, the P-type poly doped isolation structure 218 may be a trench structure form on front surface of the semiconductor layer and fill with p-type doped poly material. The P-type poly doped isolation structure 218 may be in contact with deep trench isolation structure 216. The P-type poly doped isolation structure 218 may be coupled to receive a bias voltage (e.g., ground or zero voltage) through a contact structure (such as one of contacts WC).

In various of examples, an inter-layer dielectric layer ILD included inter-layer dielectric region 24 is disposed on the semiconductor layer 210 (the first semiconductor layer). The inter-layer dielectric layer ILD may comprise oxide-based material. The inter-layer dielectric layer ILD includes a plurality of contacts WC (e.g., tungsten-based contact structure) for forming connection between one or more metal layers included in metallization layers and pixel components such as transfer gate VTX and P-type poly doped isolation structure 218 on the semiconductor layer 210. The inter-layer dielectric layer ILD may further include a semiconductor-based contact PC for providing direct connection between floating diffusion FD and TFT transistor (e.g., source of reset transistor) in formed in the TFT region 26.

The semiconductor-based contact PC may be formed of polysilicon material or amorphous silicon material. In one embodiment, the semiconductor-based contact PC may be formed by epitaxial growth using a surface region of floating diffusion FD on the semiconductor layer 210 as seeding layer. In one embodiment, the semiconductor-based contact PC may be formed by in-situ doped epitaxial growth process using a surface region of the floating diffusion FD on the semiconductor layer 210 as seeding layer.

In the illustrated embodiment, there is a contact spacing W1 between each individual contact WC and a contact spacing W2 between contact WC and semiconductor-based contact PC to ensure proper isolation. Contact spacing W1, W2 may be configured based on minimum design rule of a fabrication technology node.

The TFT region 26 includes a second semiconductor layer 260 disposed on the inter-layer dielectric layer ILD. The second semiconductor layer 260 is embedded in an upper dielectric layer 246 disposed on the inter-layer dielectric layer ILD. The second semiconductor layer 260 may be entirely embedded in the upper dielectric layer 246. The second semiconductor layer 260 may be formed of amorphous silicon or polysilicon material. The second semiconductor layer 260 is distanced from the semiconductor layer 210 in the substrate region 22 by the inter-layer dielectric layer ILD. The second semiconductor layer 260 is of a conductive type same as the floating diffusion FD. In the illustrated embodiment, the second semiconductor layer 260 is doped with a conductive type same as that of floating diffusion FD such as N-type dopant. In the illustrated embodiment, the second semiconductor layer 260 is of N polysilicon material. In some embodiments, the second semiconductor layer 260 and the semiconductor-based contact PC may have same material composition. In various of examples, the second semiconductor layer 260 may be formed using a top surface of the semiconductor-based contact PC as seeding layer. In some embodiments, the second semiconductor layer 260 and the semiconductor-based contact PC are of a monolithic structure.

In the illustrated example, the second semiconductor layer 260 has the reset transistor RST, the source follower transistor SF, and row select transistor RS formed thereon. That is, source electrodes, drain electrodes, and gate electrodes of the reset transistor RST, the source follower transistor SF, and row select transistor RS are disposed or otherwise formed on the second semiconductor layer 242. The second semiconductor layer 260 includes N-poly channel region as part of TFT transistors. The TFT region 26 includes a plurality of contacts C1˜C6. Contact C1 connects a source electrode of reset transistor RST to a corresponding metal interconnect (e.g., metal interconnect MI1 illustrated in FIG. 2B) for receiving a source bias (e.g., voltage of floating diffusion FD). Contact C2 connects a gate electrode G_{RST} of reset transistor RST to a corresponding metal interconnect (e.g., metal interconnect MI2) in the metal layer included in metallization region 28 for receiving a reset control signal RST_Sig. Contact C3 connects a drain electrode of the reset transistor RST and a drain electrode of the source follower transistor SF to a corresponding metal interconnect (e.g., metal interconnect MI3) for receiving a pixel voltage VDD as drain bias. Contact C4 connects a gate electrode G_{SF} of the source follower transistor SF to the metal interconnect (e.g., metal interconnect MI1) in the metal layer included in metallization region 28, which is also coupled to floating diffusion FD to receive voltage of floating diffusion FD. Contact C5 connects a gate electrode GRS of the row select transistor RS to a corresponding metal interconnect in the metal layer included in metallization region 28 for receiving a row select control signal RS_Sig. Contact C6 connects a source electrode of row select transistor RS to a corresponding metal interconnect for outputting signal voltage to a corresponding column bitline. Each individual of contacts C1˜C6 are spaced and electrically isolated by the upper dielectric layer 246 (e.g., oxide-based material). The plurality of contacts C1˜C6, the second semiconductor layer 260 and gate electrodes (e.g., gate electrode GRS, gate electrode G_{SF}, gate electrode G_{RST}) are embedded in the upper dielectric layer 246 included in the TFT region 26. The upper dielectric layer 246 is disposed on the inter-layer dielectric layer ILD. In some embodiments, the upper dielectric layer 246 and the inter-layer dielectric layer ILD may have same composition.

In some embodiments, there may be one or more vertical interconnections that extended from one or more metal interconnects M1, M2, M3 included in metal layer in metallization region 28 through the upper dielectric layer 246 in TFT region 26 to connect the corresponding contact PC in inter-layer dielectric layer ILD for signal routing.

FIG. 2C shows an example of stacked pixel architecture 20A with TFT transistor in accordance to another embodiment provided by the present disclosure. FIG. 2C illustrates alternate position arrangement of the second semiconductor layer 260 having TFT transistors for source follower transistor SF, reset transistor RST, and row select RS. It is appreciated that similarly named and numbered elements referenced below are coupled and function similar to as described above. It is further appreciated that stacked pixel architecture 20A of FIG. 2C shares many similarities with stacked pixel architecture 20 of FIG. 2A. As such, it is appreciated that the differences between stacked pixel architecture 20A of FIG. 2C and stacked pixel architecture 20 of FIG. 2A will be described in detail herein for the sake of brevity and in order to avoid obscuring the teachings of the present invention. In the embodiment of FIG. 2C, the second semiconductor layer 260A may be arranged to form directly above the photodiode doped region, e.g., form directly between the metal layer and the photodiode doped region (e.g., shallow PD doped region) to enable smaller pixel size e.g., reduce the additional pixel area needed for the second semiconductor layer 260A as compare to that of the stacked pixel architecture 20 of FIG. 2A. In embodiments, the source follower transistor SF, reset transistor RST, and row select RS may be disposed between the metal layer and the photodiode doped region. In embodiments, the source electrode 262 of reset transistor RST may be disposed above the floating diffusion FD. In some embodiments, the source electrode 262 of reset transistor RST may be vertical aligned with the floating diffusion FD such that semiconductor-based contact PC can be formed of a vertical structure directly connecting the source electrode 262 of reset transistor RST to floating diffusion FD.

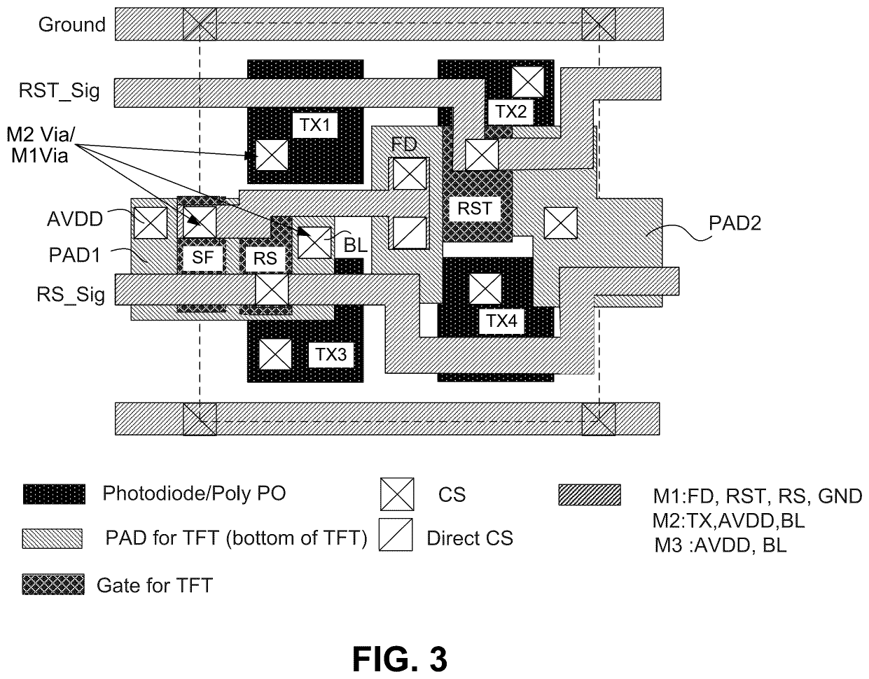

FIG. 3 shows an exemplary pixel layout for the stacked pixel architecture with TFT transistor in accordance to an embodiment provided by the present disclosure. The layer out illustrated in FIG. 3 may be a reportative pixel layout for implementing the stacked pixel architecture 20 with TFT transistor of FIG. 2A or stacked pixel architecture 20A with TFT transistor of FIG. 2C.

Photodiode/PolyPO may refer to the implantation region for forming photodiode, transfer gate on the semiconductor layer in the substrate region. PAD for TFT and Gate of TFT refers to the layout design for forming TFT transistor on the second semiconductor layer. Direct CS refers to the semiconductor-based contact PC that connecting floating diffusion to TFT transistor (e.g., reset transistor and gate of source follower) Contact CS refers to the plurality of contact WC disposed in the inter-layer dielectric ILD. Elements M1, M2 M3 may refer to metal interconnect routing design for forming metal interconnects in the metal layer included in the metallization region. In FIG. 3, there are three metal layers included in the metallization region 28, each includes corresponding metal interconnect for connection to transfer gate, bitline, ground reference line, TFT transistors such as row select transistor, source follower transistor, and reset transistor formed in the TFT region 26. As illustrated in FIG. 3, PAD1 and PAD2 are disposed at the bottom of the TFT region 26. The bottom portions PAD1 and PAD2 are disposed to avoid the transfer gates TX1 to TX4, the bit line BL, and the contact connected to the constant voltage source AVDD. The bottom portions PAD1 and PAD2 correspond to the second semiconductor layer in FIG. 2C, that is, the N-Poly channel region. In this way, contact between the conductive bottom portions PAD1 and PAD2 and the above-described contacts is avoided. As a result, conduction between the bottom portions PAD1 and PAD2 and the contacts is avoided.

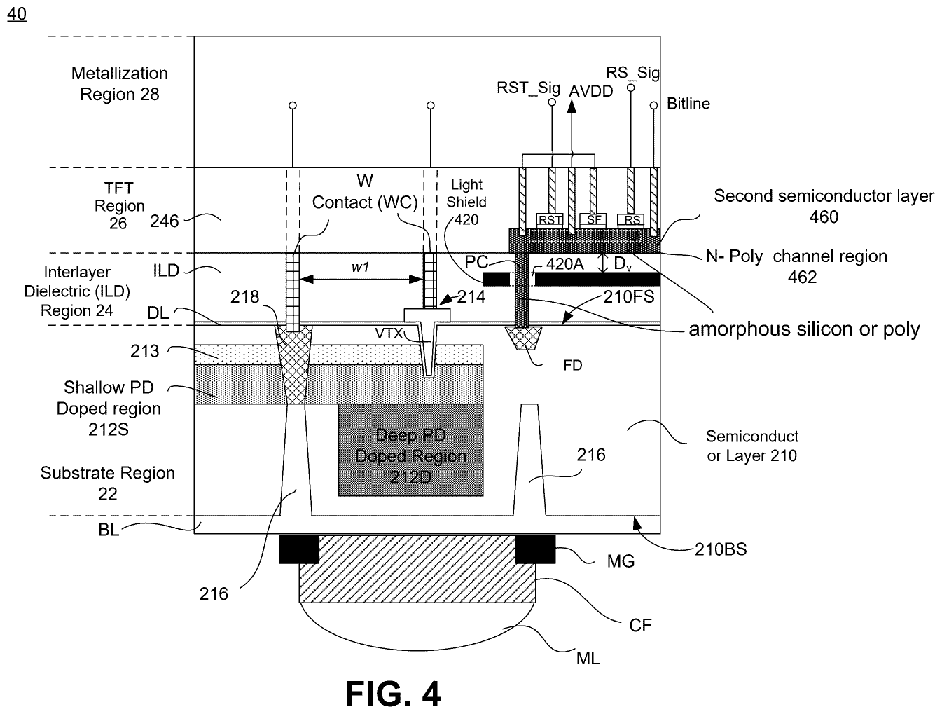

To avoid incident light reaching the second semiconductor material (i.e. PAD1, PAD2) in TFT region 26 affecting operation of TFT type pixel transistors e.g., source follower transistor, row select transistor, and reset transistor, a light shield may be employed. FIG. 4 shows an example of stacked pixel architecture 40 with a light shield structure in accordance to an embodiment provided by the present disclosure. It is appreciated that similarly named and numbered elements referenced below are coupled and function similar to as described above. A light shield 420 having an overall area larger than the second semiconductor layer 460 may be disposed between a backside surface 210FS of the semiconductor layer 210 and the second semiconductor layer 460. At least one of dimension (e.g., length or width) of the light shield 420 is greater than that of the second semiconductor layer 460. As illustrated in the exemplary cross-sectional view of FIG. 4, the light shield 420 having an overall lateral width being greater than that of the second semiconductor layer 460. The second semiconductor layer 460 has the reset transistor RST, the source follower transistor SF, and row select transistor RS formed thereon. Each of the reset transistor RST, the source follower transistor SF, and row select transistor RS further has N-type poly channel region 462 formed within the region of the second semiconductor layer 460. In the illustrated embodiment, the light shield 420 may be disposed in or otherwise embedded within the inter-layer dielectric layer ILD included inter-layer dielectric region 24 between the second semiconductor layer 460 and the front surface 210FS of the semiconductor layer 210. In some embodiments, the light shield 420 may have an opening or a hole 420A for allowing the semiconductor-based contact PC to extend through the opening or hole 420A connecting the floating diffusion FD to the source electrode of the reset transistor on the second semiconductor layer 460. For example, a diameter or an opening dimension of the opening or the hole 420A is larger than a diameter or pillar dimension of the based contact PC. By passing the based contact PC through the opening or the hole 420A, an electrical contact between the based contact PC and the light shield 420 can be avoided. That is, the semiconductor-based contact PC may extend from the source electrode of reset transistor RST through the opening or the hole 420A of the light shield 420 and land on the surface region of floating diffusion FD. The light shield 420 may be formed of metallic material or suitable light absorption material. The light shield 420 may be entirely surrounded by the inter-layer dielectric and separate from other elements such as contact WC to transfer gate. The light shield 420 may be vertically spaced from the second semiconductor layer for example by a vertical distance Dv in a direction that is perpendicular to front surface 210FS of the semiconductor layer 210, for process control and to avoid metal contamination to floating diffusion FD lead to dark current. As illustrated in FIG. 4, the second semiconductor layer 460 is electrically connected to the floating diffusion FD. In addition, as illustrated in the bottom PAD1 and PAD2 in FIG. 3, the second semiconductor layer 460 is planarly deployed on the plane of the inter-layer dielectric layer ILD. From this, it can be considered that the floating diffusion FD is connected to the bottom portions PAD1 and PAD2. When light enters the bottom portions PAD1 and PAD2, electrons may be excited in the bottom portions PAD1 and PAD2. The excited electrons may be mixed into the transfer charge from the floating diffusion FD. By protecting the second semiconductor layer 460, that is, the bottom portions PAD1 and PAD2 in FIG. 3 with the light shielding portion, charge transfer from the floating diffusion FD can be performed with high accuracy.

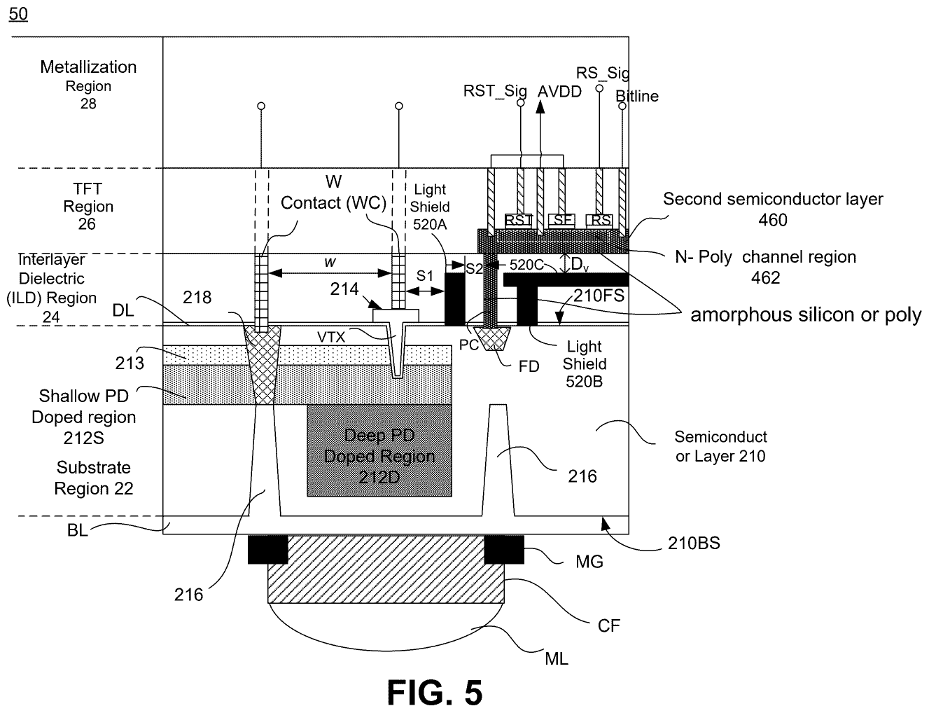

In some embodiments, light shield may also include vertical structure surrounding the semiconductor-based contact PC to prevent stray light from impinging on the semiconductor-based contact PC that is formed of amorphous silicon or polysilicon material as shown in FIG. 5, which shows an example of stacked pixel architecture 50 with a light shield 520 formed of light shield segments 520A, 520B, and 520C in accordance to another embodiment provided by the present disclosure. The light shield segment 520A may disposed between the transfer gate 214 and semiconductor-based contact PC providing vertical optical isolation. The light shield segment 520B may be disposed between the second semiconductor layer 460 and the semiconductor layer 210. Each of the light shield segments 520A and 520B may be a vertical shielding element and light shield segment 520C may be a planar shielding element. The light shield segment 520B may be disposed extending from the light shield segment 520C toward semiconductor layer 210. In some embodiments, light shield segments 520B and 520C may be monolithically formed. The light shield segment 520C may be also disposed between the second semiconductor layer 460 and the semiconductor layer 210. The light shield element 520A of the light shield 520 may be spaced properly from the transfer gate 214 with space S1 or the contact PC with space S2 to the transfer gate 214 to avoid affecting operation of transfer gate 214 (e.g., planar gate portion of transfer gate 214). The light shield segments 520A, 520B, and 520C are embedded within interlayer dielectric layer ILD and electrically isolated from transfer gate 214 and semiconductor-based contact PC. In some embodiments, the light shield segments 520A, 520B may collectively surround and shield the semiconductor-based contact PC. In some embodiments, a vertical height of the light shield segment 520A in the direction that is perpendicular to front surface 210FS of the semiconductor layer 210 is substantially the same as a combined height of the light shield segments 520B and 520C. Each of light shield segment 520A and light shield element 520C may be vertically spaced from the second semiconductor layer 460 for example by a vertical distance Dv in the direction that is perpendicular to front surface 210FS of the semiconductor layer 210.

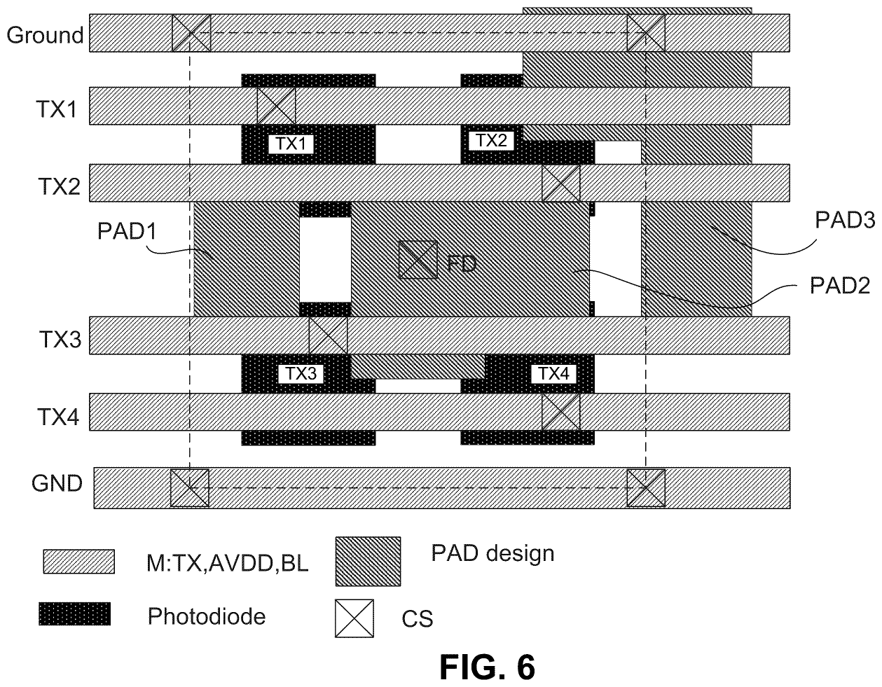

FIG. 6 shows another exemplary pixel layout for the stacked pixel architecture with TFT transistor in accordance to alternative embodiment provided by the present disclosure. FIG. 6 illustrates an example arrangement of transfer control line with respect to the floating diffusion FD, the semiconductor-based contact PC, and the TFT transistors viewing from a top view of an image sensor. The transfer control lines may be routed via metal interconnected included in metal layer in the metallization region. In this example, illustration of the gate electrode of the TFT transistor structure is omitted for simplicity.

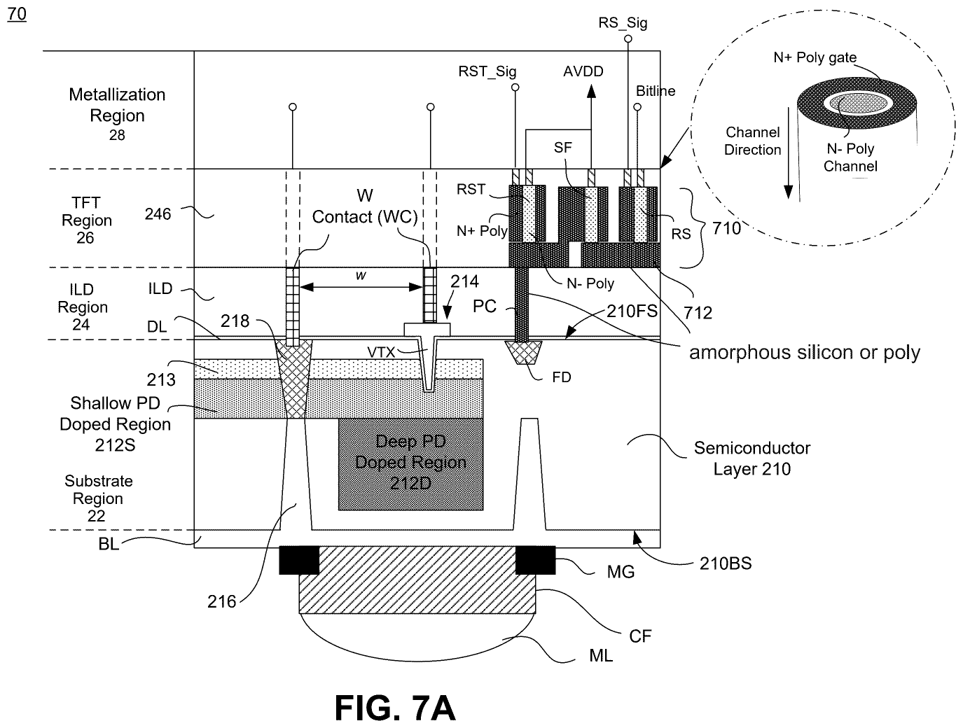

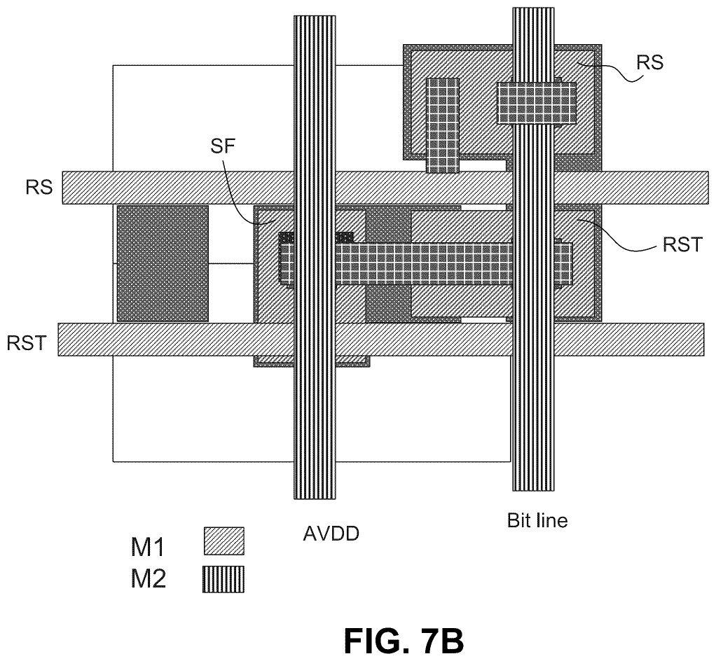

FIG. 7A illustrates an exemplary stacked pixel structure 70 for the pixel with TFT transistor included in an image sensor provided in accordance to another embodiment of the present disclosure. FIG. 7A illustrates a cylindrical type TFT transistor structure. It is appreciated that similarly named and numbered elements referenced below are coupled and function similar to as described above.

Cylindrical type TFT transistor structure 710 disposed on interlayer dielectric layer ILD include cylindrical gate structure and cylindrical source and drain electrode structure. As shown in FIG. 7A, each of pixel transistors with non-limiting examples of source follower transistor, row select transistor, and reset transistor is of cylindrical structure form with a vertical channel within the cylindrical-shaped semiconductor material 712. The gate electrode (e.g., N poly) of source follower transistor, row select transistor, and reset transistor is of vertical form surrounding its vertical channel region. The cylindrical type TFT transistor structure 710 may be entirely embedded in the upper dielectric layer 246. The cylindrical structure form of TFT transistor may be implemented utilizing the process for 3D NAND flash memory such that a smaller area can be obtained for TFT transistors, which further helps to reduce pixel size.

FIG. 7B shows an exemplary pixel layout for the stacked pixel architecture 70 with cylindrical TFT transistor illustrated in FIG. 7A in accordance to an embodiment provided by the present disclosure.

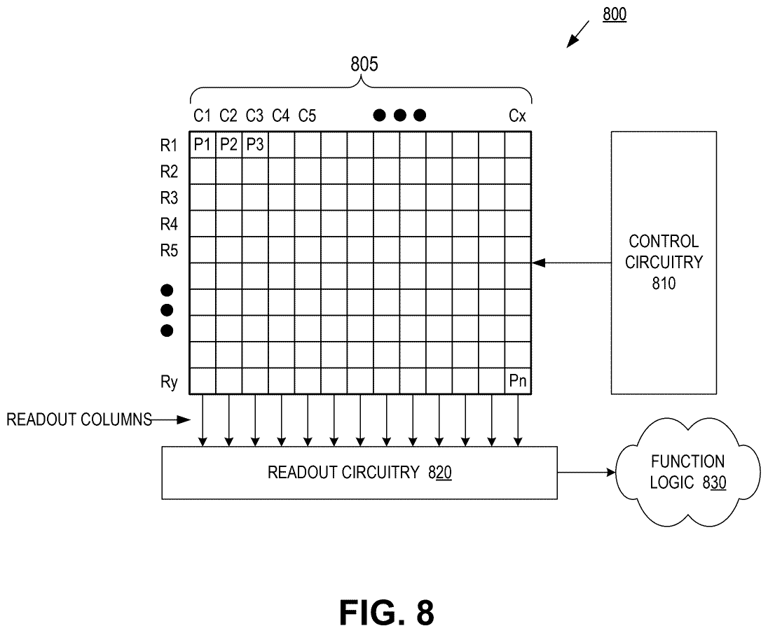

FIG. 8 illustrates a block diagram of an imaging system 800, in accordance with an embodiment of the present disclosure.

Imaging system 800 includes pixel array 805, control circuitry 810, readout circuitry 820, and function logic 830. In one embodiment, pixel array 805 is a two-dimensional (2D) array of photodiodes, or image sensor pixels (e.g., pixels P1, P2 . . . , Pn). Each individual photodiode, or image sensor pixel includes a stacking architecture of semiconductor layer and TFT transistor layer as illustrated in FIGS. 1B, 2A, 2C, 4, 5, 7A. The TFT transistor layer include TFT transistors configured as pixel transistors such as source follower transistor, reset transistor, row select transistors. As illustrated, photodiodes are arranged into rows (e.g., rows R1 to Ry) and columns (e.g., column C1 to Cx) to acquire image data of a person, place, object, etc., which can then be used to render an image or video of the person, place, object, etc. However, photodiodes do not have to be arranged into rows and columns and may take other configurations. Each of image sensor pixels may include a vertical gate structure for improving charge transfer efficiency.

In one embodiment, after each image sensor photodiode/pixel in pixel array 805 has acquired its image data or image charge, the image data is readout by readout circuitry 820 and then transferred to function logic 830. In various examples, readout circuitry 820 may include amplification circuitry, analog-to-digital (ADC) conversion circuitry, or otherwise. Function logic 830 may simply store the image data or even manipulate the image data by applying post image effects (e.g., autofocus, crop, rotate, remove red eye, adjust brightness, adjust contrast, or otherwise). In the same or another embodiment, readout circuitry 820 may readout a row of image data at a time along readout column lines (illustrated) or may readout the image data using a variety of other techniques (not illustrated), such as a serial readout or a full parallel readout of all pixels simultaneously. In one embodiment, control circuitry 830 is coupled to pixel array 805 to control operation of the plurality of image sensor pixels in pixel array 805. For example, control circuitry 810 may generate a shutter signal for controlling image acquisition. In some embodiments, control circuitry 810 may be configured to generate drive signals e.g., transfer signals, reset signals, and row-select signals for controlling the operation of pixel circuitries associated with pixels in pixel array 805.

It is appreciated that imaging system 800 may be included in a digital camera, cell phone, laptop computer, automobile, or the like. Additionally, imaging system 800 may be coupled to other pieces of hardware such as a processor (general purpose or otherwise), memory elements, output (USB port, wireless transmitter, HDMI port, etc.), lighting/flash, electrical input (keyboard, touch display, track pad, mouse, microphone, etc.), and/or display. Other pieces of hardware may deliver instructions to imaging system 800, extract image data from imaging system 800, or manipulate image data supplied by imaging system 800.

It is further appreciated that while the block diagram illustrated in FIG. 8 shows pixel array 805, readout circuitry 820, function logic 830, and control circuitry 810 as distinct and separate elements from the pixel array, this is not necessarily the case as such features may be combined or otherwise incorporated with the pixel array directly (e.g., within and/or between individual pixels, in the form of stacked substrates, or otherwise). For example, the readout circuitry 820 may include one or more transistors (e.g., associated with 3T, 4T, 5T, or other pixel architectures for reading out image charge from individual pixels), elements of which may be disposed between segments of individual photodiodes in accordance with embodiments of the present disclosure. With departing from teaching of disclosure, additional pixel transistor such as dual floating diffusion transistor, switchable conversion gain transistor, and second row select transistor, second source follower transistor, anti-blooming transistors can be configured as also using TFT transistors disposed or otherwise formed in the TFT layer as illustrated in FIGS. 1B, 2A, 2C, 4, 5, 7A. Furthermore, the image sensor 800 may include features not explicitly illustrated or discussed but known by one of ordinary skill in the art such as color filters, microlenses, a metal grids, and the like. Additionally, it is appreciated that pixel array 805 is fabricable by conventional CMOS manufacturing techniques known by one of ordinary skill in the art, which may include, but is not limited to, photolithography, chemical vapor deposition, physical vapor deposition, ion implantation or diffusion, thermal oxidation, reactive ion etching, wet chemical etching, and view of the foregoing disclosure.

In one example, imaging system 800 is implemented on a single semiconductor wafer. In another example, imaging system 800 is on stacked semiconductor wafers. For example, pixel array 805 is implemented on a pixel wafer or a sensor wafer stacking with TFT layer, and readout circuit 820, control circuit 810 and function logic 830 are implemented on an application specific integrated circuit (ASIC) wafer, where the pixel wafer and the ASIC wafer are stacked and interconnected by bonding (hybrid bonding, oxide bonding, or the like) or one or more through substrate vias (TSVs).

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

1. An image sensor, comprising:
a semiconductor layer having a first side and a second side opposite to the first side, the semiconductor layer including a photodiode doped region and a floating diffusion;
a transfer gate disposed on the semiconductor layer to couple the photodiode doped region to the floating diffusion;
an inter-layer dielectric layer on the semiconductor layer; and
an upper dielectric layer on the inter-layer dielectric layer, the upper dielectric layer including a second semiconductor layer on the inter-layer dielectric layer;
wherein the second semiconductor layer has a transistor formed thereon, the transistor coupled to the floating diffusion through a semiconductor connection structure; and
wherein the semiconductor connection structure extends through the inter-layer dielectric layer to connect a source electrode of the transistor to the floating diffusion.

2. The image sensor according to claim 1, wherein the transistor is a thin film transistor.

3. The image sensor according to claim 2, wherein the upper dielectric layer includes a first contact connecting to the source electrode of the transistor, a second contact connecting to a gate of the transistor, and a third contact connecting to a drain electrode of the transistor.

4. The image sensor according to claim 3, wherein the transistor is a reset transistor.

5. The image sensor according to claim 1, wherein the transistor is a cylindrical-type thin film transistor.

6. The image sensor according to claim 1, wherein the upper dielectric layer further includes a second transistor having a second gate disposed on the second semiconductor layer and a third transistor having a third gate disposed on the second semiconductor layer.

7. The image sensor according to claim 6, wherein the second gate of the second transistor is coupled to the source electrode of the transistor through at least one metal interconnect.

8. The image sensor according to claim 7, wherein the at least one metal interconnect is included in a metal layer disposed on the upper dielectric layer.

9. The image sensor according to claim 7, wherein the second transistor is a source follower transistor having a gate thereon, the gate coupled to the floating diffusion, and the third transistor is a row select transistor coupled to a bitline.

10. The image sensor according to claim 9, wherein the second transistor and the third transistor are TFT transistors.

11. The image sensor according to claim 10, wherein each of the second transistor and the third transistor is a cylindrical-type TFT transistor.

12. The image sensor according to claim 11, wherein each of the transistor, the second transistor, and the third transistor is a cylindrical-type TFT transistor and has a vertical channel formed in a cylindrical semiconductor material.

13. The image sensor according to claim 1, wherein the semiconductor connection structure comprises amorphous silicon or polysilicon.

14. The image sensor according to claim 1, wherein the semiconductor connection structure and the second semiconductor layer have substantially the same material composition.

15. The image sensor according to claim 1, further comprising a light shield disposed in the inter-layer dielectric layer between the second semiconductor layer and the semiconductor layer, wherein the semiconductor connection structure extends through a hole on the light shield coupling the source electrode of the transistor to the floating diffusion.

16. The image sensor according to claim 15, wherein an area of the light shield is larger than an area of the second semiconductor layer.

17. The image sensor according to claim 15, wherein the light shield comprises:
a first segment disposed in the inter-layer dielectric layer between the transfer gate and the semiconductor connection structure; and
a second segment disposed between the second semiconductor layer and the semiconductor layer.

18. The image sensor according to claim 1, wherein the second semiconductor layer and the semiconductor connection structure are of a monolithic structure.

19. The imaging sensor according to claim 1, wherein the second semiconductor layer is disposed between a metal layer on the upper dielectric layer and a part of the photodiode doped region of the photodiode.

20. The imaging sensor according to claim 1, wherein the second semiconductor layer is entirely embedded in the upper dielectric layer.
